(19) United States
(12) Patent Application Publication
(10) Pub. No.: US 2022/0178037 A1
(43) Pub. Date: Jun. 9, 2022

(54) METHOD FOR MONITORING IMPEDANCE OF ELECTROLYZER, CONTROLLER AND POWER SUPPLY

(71) Applicant: Sungrow Power Supply Co., Ltd., Hefei (CN)

(72) Inventors: Cai Jiang, Hefei (CN); Yonghao Liu, Hefei (CN); Zhixuan Fan, Hefei (CN)

(73) Assignee: Sungrow Power Supply Co., Ltd., Hefei (CN)

(21) Appl. No.: 17/355,008

(22) Filed: Jun. 22, 2021

(30) Foreign Application Priority Data
Dec. 4, 2020 (CN) 202011407054.1

(51) Int. Cl. C25B 15/023; G01R 27/16

(52) U.S. Cl. CPC C25B 15/023; C25B 1/02; G01R 27/16

(57) ABSTRACT

A method for monitoring impedance of an electrolyzer, a controller and a power supply system are provided. In the method, according to a basic electric energy command, a power supply connected with the electrolyzer is controlled to output a DC component signal used for normal operation of the electrolyzer, and according to an impedance scanning electric energy command, the power supply is controlled to output AC component signals used to monitor the impedance of the electrolyzer. Further, a voltage vector and a current vector outputted by the power supply are acquired, and an impedance value of the electrolyzer is calculated according to the voltage vector and the current vector.

This application claims the priority to Chinese Patent Application No. 202011407054.1, titled “METHOD FOR MONITORING IMPEDANCE OF ELECTROLYZER, CONTROLLER AND POWER SUPPLY”, filed on Dec. 4, 2020 with the Chinese Patent Office, which is incorporated herein by reference in its entirety.

### FIELD

The present disclosure relates to the technical field of testing, and in particular to a method for monitoring impedance of an electrolyzer, a controller and a power supply.

### BACKGROUND

An electrolyzer is a core device for converting electric energy into hydrogen energy. Impedance of the electrolyzer can indicate service life of the electrolyzer to some extent. Generally, the impedance of the electrolyzer increases with the decrease (such as decrease of catalyst activity, coating shedding) of the service life of the electrolyzer. Therefore, it is important to monitor the impedance of the electrolyzer, for maintenance of the electrolyzer.

In the conventional technology, the impedance of the electrolyzer is monitored by embedding a wire in the electrolyzer in advance and using a voltage inspection device. Alternatively, a multimeter or other tool is used to directly measure a voltage of the electrolyzer, for evaluating an operation state or service life of the electrolyzer. The above methods both require an extra testing device or tool, having a high testing cost.

### SUMMARY

In view of this, a method for monitoring impedance of an electrolyzer, a controller and a power supply system are provided according to the present disclosure, to solve the technical problem of the high testing cost caused by the extra testing device or testing tool required in the conventional technology. The technical solutions are as follows.

In a first aspect, a method for monitoring impedance of an electrolyzer is provided according to the represent disclosure. The electrolyzer is connected to a power supply, and the method includes:

acquiring a basic electric energy command and an impedance scanning electric energy command;

controlling, according to the basic electric energy command and the impedance scanning electric energy command, the power supply to output an expected electric signal, where the expected electric signal includes a direct current, DC, component signal and alternating current, AC, component signals, the DC component signal is used for normal operation of the electrolyzer, and frequencies of the AC component signals are preset frequencies in the impedance scanning electric energy command;

acquiring, for each of the preset frequencies, a voltage vector and a current vector outputted by the power supply when outputting the DC component signal and an AC component signal having the preset frequency; and

calculating, for each of the preset frequencies, according to the outputted voltage vector and the outputted current vector, an impedance value of the electrolyzer corresponding to the preset frequency.

In an embodiment, the controlling, according to the basic electric energy command and the impedance scanning electric energy command, the power supply to output an expected electric signal includes:

controlling, according to the basic electric energy command, the power supply to output the DC component signal in the expected electric signal; and

controlling, according to the impedance scanning electric energy command, the power supply to sequentially output the AC component signals respectively having the preset frequencies.

In an embodiment, the basic electric energy command is used to control a DC voltage signal outputted by the power supply, and the impedance scanning electric energy command is used to control an AC voltage signal outputted by the power supply; or the basic electric energy command is used to control a DC current signal outputted by the power supply, and the impedance scanning electric energy command is used to control an AC current signal outputted by the power supply.

In an embodiment, the basic electric energy command is used to control a DC power signal outputted by the power supply, and the impedance scanning electric energy command is used to control an AC power signal outputted by the power supply.

In an embodiment, the power supply includes a first power supply and a second power supply, and the process of controlling, according to the basic electric energy command and the impedance scanning electric energy command, the power supply to output an expected electric signal includes:

controlling, according to the basic electric energy command, the first power supply to output the DC component signal in the expected electric signal; and

controlling, according to the impedance scanning electric energy command, the second power supply to sequentially output the AC component signals respectively having the preset frequencies.

In an embodiment, the basic electric energy command is used to control a DC voltage signal outputted by the first power supply, and the impedance scanning electric energy command is used to control an AC voltage signal outputted by the second power supply; or the basic electric energy command is used to control a DC current signal outputted by the first power supply, and the impedance scanning electric energy command is used to control an AC current signal outputted by the second power supply.

In an embodiment, the basic electric energy command is used to control a DC power signal outputted by the first power supply, and the impedance scanning electric energy command is used to control an AC power signal outputted by the second power supply.

In an embodiment, the acquiring, for each of the preset frequencies, a voltage vector and a current vector outputted by the power supply when outputting the DC component signal and an AC component signal having the preset frequency includes:

receiving the voltage vector from a voltage sensor connected with an output end of the power supply; and

receiving the current vector from a current sensor connected with the output end of the power supply.

In a second aspect, a controller is further provided according to the present disclosure. The controller is used to monitor impedance of an electrolyzer. The controller includes a memory and a processor. The memory stores a program. The processor is configured to execute the program to perform the method for monitoring impedance of an electrolyzer according to the first aspect.

In a third aspect, a power supply system is further provided according to the present disclosure. The power supply system provides electric energy for an electrolyzer. The power supply system includes a power supply and a controller. An output end of the power supply is connected with a voltage sensor and a current sensor, and the output end of the power supply is connected with a power input end of the electrolyzer. The controller is configured to acquire a basic electric energy command and an impedance scanning electric energy command; control, according to the basic electric energy command and the impedance scanning electric energy command, the power supply to output an expected electric signal, where the expected electric signal includes a direct current, DC, component signal and alternating current, AC, component signals, the DC component signal is used for normal operation of the electrolyzer, and frequencies of the AC component signals are preset frequencies in the impedance scanning electric energy command; acquire, for each of the preset frequencies, a voltage vector and a current vector outputted by the power supply when outputting the DC component signal and an AC component signal having the preset frequency; and calculate, for each of the preset frequencies, according to the outputted voltage vector and the outputted current vector, an impedance value of the electrolyzer corresponding to the preset frequency.

In an embodiment, the controller is configured to:

control, according to the basic electric energy command, a DC voltage signal outputted by the power supply; and control, according to the impedance scanning electric energy command, an AC voltage signal outputted by the power supply; or

control, according to the basic electric energy command, a DC current signal outputted by the power supply; and control, according to the impedance scanning electric energy command, an AC current signal outputted by the power supply; or

control, according to the basic electric energy command, a DC power signal outputted by the power supply; and control, according to the impedance scanning electric energy command, an AC power signal outputted by the power supply.

In an embodiment, the power supply includes a first power supply and a second power supply. The controller is configured to:

control, according to the basic electric energy command, the first power supply to output the DC component signal in the expected electric signal; and

control, according to the impedance scanning electric energy command, the second power supply to sequentially output the AC component signals respectively having the preset frequencies.

In an embodiment, the power supply includes a first power supply and a second power supply, and the controller includes a first controller and a second controller. The first controller is configured to control, according to the basic electric energy command, a DC voltage signal, a DC signal or a DC power signal outputted by the first power supply. The second controller is configured to control, according to the impedance scanning electric energy command, an AC voltage signal, an AC signal or an AC power signal outputted by the second power supply.

In an embodiment, the second power supply and the second controller are integrated into an impedance monitoring device independent of first power supply and the first controller.

In the method for monitoring impedance of an electrolyzer according to the present disclosure, during the operation of the electrolyzer, an AC component signal is added to an electric signal inputted into the electrolyzer, to acquire an impedance value of the electrolyzer. Specifically, according to a basic electric energy command, a power supply connected with the electrolyzer is controlled to output a DC component signal for the normal operation of the electrolyzer, and according to an impedance scanning electric energy command, the power supply is controlled to output AC component signals used to monitor the impedance of the electrolyzer. A voltage vector and a current vector outputted by the power supply are acquired, and the impedance value of the electrolyzer is calculated according to the voltage vector and the current vector. With this method, the impedance scanning can be performed in a real-time manner during the normal operation of the electrolyzer, to calculate the impedance value of the electrolyzer, so as to evaluate the operation state and the service life of the electrolyzer. Moreover, the above process according to the present disclosure only requires hardware devices of the power supply without extra hardware devices, so that the hardware cost is reduced, and the safety of the process for monitoring the impedance of the electrolyzer is improved.

### BRIEF DESCRIPTION OF THE DRAWINGS

In order to more clearly illustrate technical solutions in embodiments of the present disclosure or in the conventional technology, the drawings to be used in the description of the embodiments or the conventional technology are briefly described below. Apparently, the drawings in the following description show only some embodiments of the present disclosure, and other drawings may be obtained by those skilled in the art from the drawings without any creative work.

FIG. 1 is a schematic diagram of an electrolyzer impedance model according to an embodiment of the present disclosure;

FIG. 2 is a schematic diagram of an impedance spectroscopy curve of an electrolyzer;

FIG. 3 is a flow chart of a method for monitoring impedance of an electrolyzer according to an embodiment of the present disclosure;

FIG. 4 is a schematic structural diagram of a power supply system of an electrolyzer according to an embodiment of the present disclosure;

FIG. 5 is a schematic structural diagram of a power supply system of an electrolyzer according to another embodiment of the present disclosure;

FIG. 6 is a schematic structural diagram of a power supply system of an electrolyzer according to another embodiment of the present disclosure; and

FIG. 7 is a schematic structural diagram of a power supply system of an electrolyzer according to another embodiment of the present disclosure.

### DETAILED DESCRIPTION

In order to make objects, technical solutions and advantages of the present disclosure clearer, the technical solutions the embodiments of the present disclosure are further described clearly and completely with reference to the drawings in the embodiments of the present disclosure hereinafter. It is apparent that the described embodiments are only some embodiments of the present disclosure, rather than all embodiments. All other embodiments obtained by those skilled in the art based on the embodiments of the present disclosure without any creative work fall within the protection scope of the present disclosure.

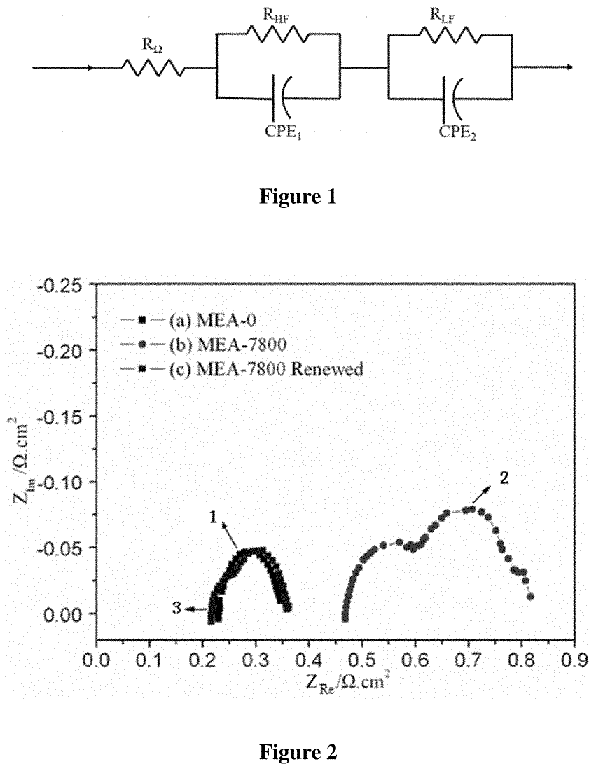

An equivalent model of the electrolyzer is shown in FIG. 1. The impedance of the electrolyzer has a resistive-capacitive characteristic, mainly including a resistive component. FIG. 2 is a schematic diagram of an impedance spectroscopy curve of the electrolyzer, in which a horizontal axis represents a real part of an impedance value and a vertical axis represents an imaginary part of the impedance value. A complete impedance curve can be acquired by acquiring impedance values corresponding to different frequency scanning points are acquired through an impedance scanning signal.

The operation state and service life of the electrolyzer can be determined from the monitored impedance of the electrolyzer. The impedance of the electrolyzer increases with the decrease of the service life of the electrolyzer. As shown in FIG. 2, impedance of a newly produced electrolyzer is shown as the curve 1, then the impedance is changed to the curve 2 after the electrolyzer is used for a time period (for example, 7800 hours), and then the impedance is changed to the curve 3 after the electrolyzer is repaired and maintained.

By comparing the curve 1 and the curve 2, it can be seen that the overall impedance curve of the electrolyzer moves to the right of the curve 1 after the electrolyzer is used for a time period, indicating increased impedance. After the electrolyzer is repaired and maintained, the impedance curve substantially coincides with the curve 1 of the impedance of the original electrolyzer, indicating that the impedance returns to the original state.

In addition, a starting point on the left side of the curve indicates the resistive impedance of the electrolyzer. A diameter of a curve segment on the right side of the curve indicates the performance of an anode catalyst, and a diameter of a curve segment on the left side of the curve indicates the performance of a cathode catalyst. A small diameter indicates a good performance of the catalyst. Therefore, based on the above theory, the impedance, the service life and the maintenance situation of the electrolyzer can be acquired by analyzing the impedance curve.

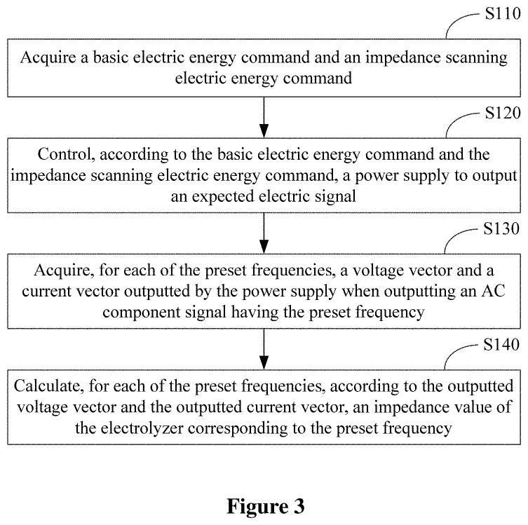

Reference is made to FIG. 3, which is a flow chart of a method for monitoring impedance of an electrolyzer according to an embodiment of the present disclosure. The method is applied to a power supply system of an electrolyzer.

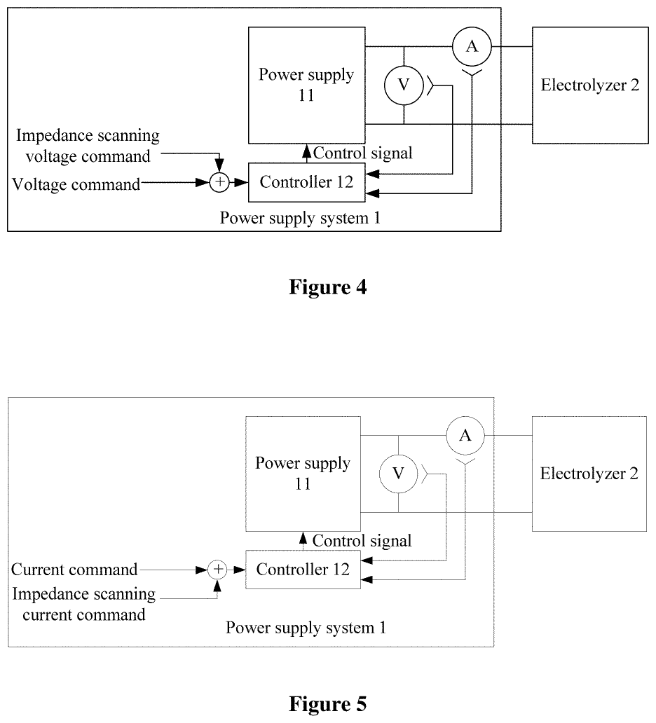

In an embodiment of the present disclosure, as shown in FIG. 4, a power supply system 1 of an electrolyzer includes a power supply 11 and a controller 12.

The power supply 11 provides electric energy for an electrolyzer 2. The controller 12 controls an electric signal outputted by the power supply 11.

An output end of the power supply 11 is connected with a voltage sensor V and a current sensor A. The output end of the power supply 11 may be connected in parallel with the voltage sensor V to form a parallel branch and then the parallel branch is connected in series with the current sensor A. Alternatively, the output end of the power supply 11 may be connected in series with the current sensor A to form a series branch and then the series branch is connected in parallel with the voltage sensor V.

The method for monitoring impedance of an electrolyzer is described with reference to FIG. 3 below. The method is applied to the controller 12. As shown in FIG. 3, the method includes the following steps S110 to S140.

In step S110, a basic electric energy command and an impedance scanning electric energy command are acquired.

In an embodiment of the present disclosure, the basic electric energy command and the impedance scanning electric energy command may be generated by the controller 12, or may be received from outside.

In an embodiment, as shown in FIG. 4, both the basic electric energy command and the impedance scanning electric energy command are voltage commands.

The basic electric energy command is used to control the power supply to output a DC voltage signal corresponding to the basic electric energy command. The impedance scanning electric energy command is used to control the power supply to output an AC voltage signal corresponding to the impedance scanning electric energy command.

The method of voltage control is commonly used in the initial commissioning of the electrolyzer to test whether a basic function of the electrolyzer is normal.

In another embodiment, as shown in FIG. 5, both the basic electric energy command and the impedance scanning electric energy command are current commands.

The basic electric energy command is used to control the power supply to output a DC current signal corresponding to the basic electric energy command. The impedance scanning electric energy command is used to control the power supply to output an AC current signal corresponding to the impedance scanning electric energy command.

The method of current control is commonly used in the normal operation of the electrolyzer. The reason is that a functional relationship exists between a current and gas amount of hydrogen/oxygen produced by the electrolyzer, so that the amount of produced gas can be calculated according to the current value. In other words, the current command can be changed according to a gas production demand, to regulate the actual gas production.

In another embodiment of the present disclosure, the basic electric energy command and the impedance scanning electric energy command are used to control an output power of the power supply. Specifically, the output power is controlled by controlling an output current and/or an output voltage of the power supply.

In step S120, the power supply is controlled to output an expected electric signal according to the basic electric energy command and the impedance scanning electric energy command.

The expected electric signal includes a DC component signal and AC component signals. The DC component signal is used for normal operation of the electrolyzer. Frequencies of the AC component signals are preset frequencies in the impedance scanning electric energy command.

The preset frequencies may include multiple different frequencies.

In step S130, for each of the preset frequencies, a voltage vector and a current vector outputted by the power supply when outputting the DC component signal and an AC component signal having the preset frequency are acquired.

The voltage sensor acquires, for each of the preset frequencies, a voltage vector outputted by the power supply 11 when outputting the AC component signal having the preset frequency and transmits the voltage vector to the controller 12. In addition, the current sensor acquires, for each of the preset frequencies, a current vector outputted by the power supply 11 when outputting the AC component signal having the preset frequency, and transmits the current sensor to the controller 12.

In step S140, for at least one of the preset frequencies, an impedance value of the electrolyzer corresponding to the preset frequency is calculated according to the outputted voltage vector and the outputted current vector.

The voltage vector includes a voltage amplitude and a voltage phase. Similarly, the current vector includes a current amplitude and a current phase. The impedance value of the electrolyzer is calculated according to the voltage amplitude, the current amplitude and a difference between the voltage phase and the current phase.

In the normal operation, the electrolyzer can be equivalent to a model having resistive-capacitive impedance, mainly including resistive impedance. The operating power for the electrolyzer is DC power. Therefore, the electrolyzer under the normal operation condition is considered as a resistor. The resistance of the resistor is mainly related to a temperature of the electrolyzer and a current flowing through the electrolyzer. Heat capacity of water and heat capacity of a metal structure of the electrolyzer are two main parts of the heat capacity of the electrolyzer, which are both high so that the temperature changes slowly. Therefore, the temperature is approximately regarded as unchanged in seconds. Therefore, the impedance curve of the electrolyzer can be acquired by regulating the impedance scanning electric energy command, or regulating the impedance scanning electric energy command and the basic electric energy command.

In the method for monitoring impedance of an electrolyzer according to the embodiment, during the operation of the electrolyzer, an AC component signal is added to an electric signal inputted into the electrolyzer, to acquire an impedance value of the electrolyzer. Specifically, according to a basic electric energy command, a power supply connected with the electrolyzer is controlled to output a DC component signal for the normal operation of the electrolyzer, and according to an impedance scanning electric energy command, the power supply is controlled to output AC component signals used to monitor the impedance of the electrolyzer. A voltage vector and a current vector outputted by the power supply are acquired, and the impedance value of the electrolyzer is calculated according to the voltage vector and the current vector. With this method, the impedance scanning can be performed in a real-time manner during the normal operation of the electrolyzer, to calculate the impedance value of the electrolyzer, so as to evaluate the operation state and the service life of the electrolyzer. Moreover, the above process according to the present disclosure only requires hardware devices of the power supply without extra hardware devices, so that the hardware cost is reduced, and the safety of the process for monitoring the impedance of the electrolyzer is improved.

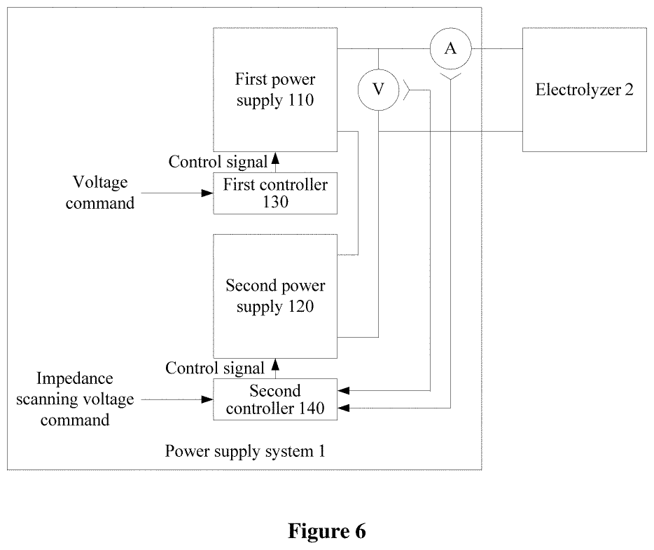

Reference is made to FIG. 6, which is a schematic structural diagram of a power supply system of an electrolyzer according to another embodiment of the present disclosure. In the embodiment, a power supply system 1 includes a first power supply 110, a second power supply 120, a first controller 130 and a second controller 140.

An output end of the first power supply 110 is connected in series with an output end of the second power supply 120 to form a series branch, and then the series branch is connected with a power input end of an electrolyzer 2. In addition, an output end of the power supply system is connected in series with a current sensor A, and the output end of the power supply system is connected in parallel with a voltage sensor V.

The first controller 130 is configured to acquire a basic electric energy command, and control the first power supply 110 to output an expected DC electric signal according to the basic electric energy command.

The second controller 140 is configured to acquire an impedance scanning electric energy command, and control the second power supply 120 to output an expected AC electric signal according to the impedance scanning electric energy command.

In an embodiment of the present disclosure, the outputted voltage vector acquired by the voltage sensor and the outputted current vector acquired by the current sensor may be transmitted to the first controller 130, so that the first controller calculates an impedance value of the electrolyzer according to the outputted voltage vector and the outputted current vector.

In another embodiment, the second controller 140 receives the outputted voltage vector and the outputted current vector, and calculates the impedance value of the electrolyzer according to the outputted voltage vector and the outputted current vector.

In other embodiment of the present disclosure, the functions of the first controller 130 and the second controller 140 may be integrated into one controller, thereby reducing the hardware cost.

In the embodiment, both the basic electric energy command and the impedance scanning electric energy command are voltage commands, that is, the first controller and the second controller are configured to control voltage signals outputted by the power supply system.

In the embodiment, the DC electric signal required for the normal operation of the electrolyzer is provided and controlled according to the actual gas production demand of the electrolyzer by using the first power supply and the first controller. In addition, the AC electric signals for impedance scanning are provided by using the second power supply and the second controller.

In other embodiment of the present disclosure, in order to share the second power supply and the second controller by multiple electrolyzers, the second power supply and the second controller are integrated into an impedance monitoring device independent of the first power supply and the first controller. The impedance monitoring device only provides the AC component signals for impedance scanning, which does not require a wire embedded in the electrolyzer in advance, or an extra device for measuring an electric signal.

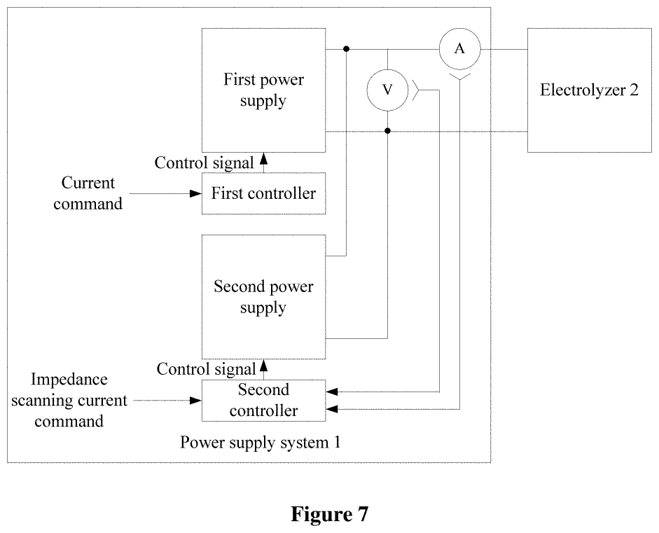

In another embodiment of the present disclosure, as shown in FIG. 7, both the basic electric energy command and the impedance scanning electric energy command are current commands.

The first controller is configured to control a DC current signal outputted by the first power supply according to the basic electric energy command. The second controller is configured to control an AC current signal outputted by the second power supply according to the impedance scanning electric energy command.

Similar to the embodiment shown in FIG. 6, the functions of the first controller and the second controller may be integrated into one controller, thereby reducing the hardware cost.

The second power supply and the second controller may also be integrated into an independent impedance monitoring device.

In the power supply system according to the embodiments shown in FIG. 6 and FIG. 7, the first power supply and the second power supply can operate independently of each other. Moreover, the second power supply and the second controller may be integrated into an independent impedance monitoring device that can be applied to multiple electrolyzers, which is convenient and universal.

In another aspect, a controller is further provided according to the present disclosure. The controller includes a processor and a memory. The memory stores a program executable by the processor. The processor is configured to execute the program stored in the memory, to perform the above method for monitoring impedance of an electrolyzer.

A storage medium for a computer device is further provided according to the present disclosure. The storage medium stores a program. The program, when being executed by the computer device, performs the above method for monitoring impedance of an electrolyzer.

The foregoing embodiments of the method are described as combinations of series of actions for convenience of the descriptions. However, those skilled in the art should understand that, since some of the steps may be performed in a different sequence or simultaneously according to the present disclosure, the described sequence of actions is not intended to limit the present disclosure. In addition, those skilled in the art should understand that the described embodiments in the description are all preferred embodiments, and actions and modules involved in embodiments may not be necessary for the present disclosure.

It should be noted that technical features in different embodiments of the present disclosure may be replaced or combined with each other. Each of the embodiments emphasizes the differences from others, and the same or similar parts among the embodiments can be referred to each other. Since the device according to the embodiments is similar to the method therein, the description thereof is relatively simple, and for relevant matters references may be made to the description of the method.

The sequence of the steps in the method according to the embodiments of the present disclosure may be adjusted, and the steps may be combined or removed according to actual requirements.

The modules and sub-modules in the device and the terminal according to the embodiments of the present disclosure may be adjusted, divided or removed according to actual requirements.

In the embodiments described in the present disclosure, it should be understood that the terminal, device and method described herein may be implemented in other ways. For example, the terminal embodiments described above are illustrative only. For example, the modules or sub-modules are divided merely in logical function, which may be divided by another way in actual implementation. For example, multiple sub-modules or modules may be combined or integrated into another system, or some features may be ignored or not performed. In addition, the shown or discussed coupling or communication connection may be direct coupling or may be implemented via some interfaces, devices or modules, and may be electrical, mechanical or in other forms.

The modules or sub-modules described as a separate component may be or may be not separated physically. The component displayed as a module or sub-module may be or may be not a physical module or a physical sub-module, that is, may be located at one place or may be distributed on multiple network modules or multiple network sub-modules. The object of the solution of the embodiment may be achieved by selecting a part or all of the modules or the sub-modules according to the actual requirements.

Furthermore, functional modules or sub-modules in different embodiments of the present disclosure may be integrated into one processing module, or may be separate physical modules or sub-modules respectively. Alternatively, two or more modules or sub-modules may be integrated into one module. The integrated module or sub-module may be implemented in a form of hardware, or may be implemented in a form of a software functional module or sub-module.

Finally, it should be further noted that the relationship terminologies such as first, second or the like are only used herein to distinguish one entity or operation from another, rather than to necessitate or imply that the actual relationship or order exists between the entities or operations. Furthermore, terms of “include”, “comprise” or any other variants are intended to be non-exclusive. Therefore, a process, method, article or device including a series of elements includes not only the elements but also other elements that are not enumerated, or also includes the elements inherent for the process, method, article or device. Unless expressively limited otherwise, the statement “comprising (including) one . . . ” does not exclude the case that other similar elements may exist in the process, method, article or device.

Based on the above description of the disclosed embodiments, those skilled in the art can implement or carry out the present disclosure. It is apparent for those skilled in the art to make many modifications to these embodiments. The general principle defined herein may be applied to other embodiments without departing from the spirit or scope of the present disclosure. Therefore, the present disclosure is not limited to the embodiments illustrated herein, but should be defined by the widest scope consistent with the principle and novel features disclosed herein.

Only preferred embodiments of the present disclosure are described above. It should be noted that for those skilled in the art, various improvements and modifications can be made without departing from the principle of the present disclosure, and these improvements and modifications should fall within the scope of protection of the present disclosure.

1. A method for monitoring impedance of an electrolyzer, wherein the electrolyzer is connected to a power supply, and the method comprises:
acquiring a basic electric energy command and an impedance scanning electric energy command;
controlling, according to the basic electric energy command and the impedance scanning electric energy command, the power supply to output an expected electric signal, wherein the expected electric signal comprises a direct current (DC) component signal and alternating current (AC) component signals, the DC component signal is used for normal operation of the electrolyzer, and frequencies of the AC component signals are preset frequencies in the impedance scanning electric energy command;
acquiring, for each of the preset frequencies, a voltage vector and a current vector outputted by the power supply when outputting the DC component signal and an AC component signal having the preset frequency; and
calculating, for each of the preset frequencies, according to the outputted voltage vector and the outputted current vector, an impedance value of the electrolyzer corresponding to the preset frequency.

2. The method according to claim 1, wherein the controlling, according to the basic electric energy command and the impedance scanning electric energy command, the power supply to output an expected electric signal comprises:
controlling, according to the basic electric energy command, the power supply to output the DC component signal in the expected electric signal; and
controlling, according to the impedance scanning electric energy command, the power supply to sequentially output the AC component signals respectively having the preset frequencies.

3. The method according to claim 2, wherein
the basic electric energy command is used to control a DC voltage signal outputted by the power supply, and the impedance scanning electric energy command is used to control an AC voltage signal outputted by the power supply; or
the basic electric energy command is used to control a DC current signal outputted by the power supply, and the impedance scanning electric energy command is used to control an AC current signal outputted by the power supply.

4. The method according to claim 2, wherein the basic electric energy command is used to control a DC power signal outputted by the power supply, and the impedance scanning electric energy command is used to control an AC power signal outputted by the power supply.

5. The method according to claim 1, wherein the power supply comprises a first power supply and a second power supply, and the controlling, according to the basic electric energy command and the impedance scanning electric energy command, the power supply to output an expected electric signal comprises:
controlling, according to the basic electric energy command, the first power supply to output the DC component signal in the expected electric signal; and
controlling, according to the impedance scanning electric energy command, the second power supply to sequentially output the AC component signals respectively having the preset frequencies.

6. The method according to claim 5, wherein
the basic electric energy command is used to control a DC voltage signal outputted by the first power supply, and the impedance scanning electric energy command is used to control an AC voltage signal outputted by the second power supply; or
the basic electric energy command is used to control a DC current signal outputted by the first power supply, and the impedance scanning electric energy command is used to control an AC current signal outputted by the second power supply.

7. The method according to claim 5, wherein
the basic electric energy command is used to control a DC power signal outputted by the first power supply, and the impedance scanning electric energy command is used to control an AC power signal outputted by the second power supply.

8. The method according to claim 1, wherein the acquiring, for each of the preset frequencies, a voltage vector and a current vector outputted by the power supply when outputting the DC component signal and an AC component signal having the preset frequency comprises:
receiving the voltage vector from a voltage sensor connected with an output end of the power supply; and
receiving the current vector from a current sensor connected with the output end of the power supply.

9. A controller for monitoring impedance of an electrolyzer, comprising:
a memory, storing a program; and
a processor, configured to execute the program to:
acquire a basic electric energy command and an impedance scanning electric energy command;
control, according to the basic electric energy command and the impedance scanning electric energy command, a power supply to output an expected electric signal, wherein the expected electric signal comprises a direct current (DC) component signal and alternating current (AC) component signals, the DC component signal is used for normal operation of the electrolyzer, and frequencies of the AC component signals are preset frequencies in the impedance scanning electric energy command;
acquire, for each of the preset frequencies, a voltage vector and a current vector outputted by the power supply when outputting the DC component signal and an AC component signal having the preset frequency; and
calculate, for each of the preset frequencies, according to the outputted voltage vector and the outputted current vector, an impedance value of the electrolyzer corresponding to the preset frequency.

10. The controller according to claim 9, wherein the processor is configured to execute the program to:
control, according to the basic electric energy command, the power supply to output the DC component signal in the expected electric signal; and
control, according to the impedance scanning electric energy command, the power supply to sequentially output the AC component signals respectively having the preset frequencies.

11. The controller according to claim 10, wherein
the basic electric energy command is used to control a DC voltage signal outputted by the power supply, and the impedance scanning electric energy command is used to control an AC voltage signal outputted by the power supply; or
the basic electric energy command is used to control a DC current signal outputted by the power supply, and the impedance scanning electric energy command is used to control an AC current signal outputted by the power supply.

12. The controller according to claim 10, wherein the basic electric energy command is used to control a DC power signal outputted by the power supply, and the impedance scanning electric energy command is used to control an AC power signal outputted by the power supply.

13. The controller according to claim 9, wherein the processor is configured to execute the program to:
control, according to the basic electric energy command, a first power supply comprised in the power supply to output the DC component signal in the expected electric signal; and
control, according to the impedance scanning electric energy command, a second power supply comprised in the power supply to sequentially output the AC component signals respectively having the preset frequencies.

14. A power supply system for an electrolyzer, comprising:
a power supply, wherein an output end of the power supply is connected with a voltage sensor and a current sensor, and the output end of the power supply is connected with a power input end of the electrolyzer; and
a controller, configured to:
acquire a basic electric energy command and an impedance scanning electric energy command;
control, according to the basic electric energy command and the impedance scanning electric energy command, the power supply to output an expected electric signal, wherein the expected electric signal comprises a direct current, DC, component signal and alternating current, AC, component signals, the DC component signal is used for normal operation of the electrolyzer, and frequencies of the AC component signals are preset frequencies in the impedance scanning electric energy command;
acquire, for each of the preset frequencies, a voltage vector and a current vector outputted by the power supply when outputting the DC component signal and an AC component signal having the preset frequency; and
calculate, for each of the preset frequencies, according to the outputted voltage vector and the outputted current vector, an impedance value of the electrolyzer corresponding to the preset frequency.

15. The power supply system according to claim 14, wherein the controller is configured to:
control, according to the basic electric energy command, a DC voltage signal outputted by the power supply; and control, according to the impedance scanning electric energy command, an AC voltage signal outputted by the power supply; or
control, according to the basic electric energy command, a DC current signal outputted by the power supply; and control, according to the impedance scanning electric energy command, an AC current signal outputted by the power supply; or
control, according to the basic electric energy command, a DC power signal outputted by the power supply; and control, according to the impedance scanning electric energy command, an AC power signal outputted by the power supply.

16. The power supply system according to claim 14, wherein
the power supply comprises a first power supply and a second power supply; and
the controller is configured to:
control, according to the basic electric energy command, the first power supply to output the DC component signal in the expected electric signal; and
control, according to the impedance scanning electric energy command, the second power supply to sequentially output the AC component signals respectively having the preset frequencies.

17. The power supply system according to claim 14, wherein
the power supply comprises a first power supply and a second power supply; and
the controller comprises a first controller and a second controller; wherein
the first controller is configured to control a DC voltage signal, a DC current signal or a DC power signal outputted by the first power supply, according to the basic electric energy command; and
the second controller is configured to control, an AC voltage signal, an AC current signal or an AC power signal outputted by the second power supply, according to the impedance scanning electric energy command.

18. The power supply system according to claim 17, wherein the second power supply and the second controller are integrated into an impedance monitoring device independent of the first power supply and the first controller.
